(19) United States
(12) Patent Application Publication
(10) Pub. No.: US 2010/0073882 A1
(43) Pub. Date: Mar. 25, 2010

(54) THERMALLY CONDUCTIVE SHEET, PROCESS FOR PRODUCING THE SAME, AND RADIATOR UTILIZING THERMALLY CONDUCTIVE SHEET

(76) Inventors: Tooru Yoshikawa, Ibaraki (JP); Michiaki Yajima, Ibaraki (JP); Teiichi Inada, Ibaraki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/513,194

(22) PCT Filed: Oct. 29, 2007
(86) PCT No.: PCT/JP2007/071038

§ 371 Date: May 1, 2009

(30) Foreign Application Priority Data
Nov. 1, 2006 (JP) 2006-297730
Jul. 18, 2007 (JP) 2007-187119

(51) Int. Cl. H05K 7/20; B32B 27/18; B32B 38/04; B32B 38/10; F28F 21/02; H01L 23/36

(52) U.S. Cl. 361/707; 428/323; 428/212; 156/242; 156/244.24; 156/193; 165/185

(57) ABSTRACT

A thermally conductive sheet having both of a high thermal conductivity and a high flexibility is obtained by providing a thermally conductive sheet including a composition containing:
graphite particles (A) in the form of a scale, an elliptic sphere or a rod, a 6-membered ring plane in a crystal thereof being oriented in the plane direction of the scale, the major axis direction of the elliptic sphere, or the major axis direction of the rod; and
an organic polymeric compound (B) having a Tg of 50° C. or lower,
wherein the plane direction of the scale, the major axis direction of the elliptic sphere, or the major axis direction of the rod of the graphite particles (A) is oriented in the thickness direction of the thermally conductive sheet, the area of the graphite particles (A) exposed onto surfaces of the thermally conductive sheet is 25% or more and 80% or less, and the Ascar C hardness of the sheet is 60 or less at 70° C.

Further there is provided a process for producing, without fail, a thermally conductive sheet advantageously for productivity, costs and energy efficiency and a radiator having a high heat radiating capability.

### TECHNICAL FIELD

The present invention relates to a thermally conductive sheet, a process for producing the same, and a radiator utilizing a thermally conductive sheet.

### BACKGROUND ART

In recent years, for multi layer interconnection boards or semiconductor packages, the density of interconnections has been becoming high or the density of mounted electronic components has been becoming large. Moreover, the integration degree of semiconductor elements has become high so that the amount of heat generated per unit area has turned large. For this reason, it has been desired to make heat radiation from semiconductor packages better.

In general, a radiator is conveniently used wherein a thermally conductive grease or thermally conductive sheet is sandwiched between a heat generating body, such as a semiconductor package, and a heat radiating body, such as aluminum or copper to cause them to adhere closely to each other, thereby radiating heat. The thermally conductive sheet is better in workability than the thermally conductive grease when the radiator is fabricated. In order to make the heat radiating performance better, the thermally conductive sheet is required to have a high thermal conductivity. However, it cannot be necessarily said that the thermal conductivity of conventional thermally conductive sheets is sufficient.

Thus, in order to improve the thermal conductivity of thermally conductive sheets further, suggested are various thermally conductive composite material compositions wherein graphite powder, which has a large thermal conductivity, is blended into a matrix material, and formed and processed products therefrom.

For example, JP-A-62-131033 discloses a thermally conductive resin formed body wherein graphite powder is filled into a thermoplastic resin, and JP-A-04-246456 discloses a polyester resin composition containing graphite, carbon black and the like. Moreover, JP-A-05-247268 discloses a rubber composition into which an artificial graphite having a particle diameter of 1 to 20 μm is blended, and JP-A-10-298433 discloses a composition wherein a spherical graphite powder having a crystal face interstice of 0.330 to 0.340 nm is blended into a silicone rubber. JP-A-11-001621 describes a highly thermally conductive composite material characterized by compressing specified graphite particles in a solid body under pressure, thereby aligning the particles in parallel to surfaces of the composition, and a process for producing the material. Furthermore, JP-A-2003-321554 discloses a thermally conductive formed body wherein the c axis of the crystal structure of graphite powder is oriented in a direction perpendicular to the direction in which heat is conducted, and a process for producing the same.

Thermally conductive sheets have an advantage that the workability thereof is simple when a radiator is fabricated therefrom, as described above. For a using manner for making good use of this advantage, needs have been generated that the sheets should be caused to have a property of following especial forms, such as irregularities or a curved surface, a function such as relieving stress. For example, in heat radiation from a large area, such as that from a display panel, a thermally conductive sheet therefor is required to have: a property of following distortions of surfaces of its heat generating body and radiating body or forms such as irregularities thereof; a function such as reliving thermal stress generated by a difference in thermal expansion coefficient therebetween. The thermally conductive sheet has been required to have a high flexibility besides such a high thermal conductivity that the sheet can conduct heat even when the thickness of the sheet is large to some degree. However, a thermally conductive sheet has not yet been obtained wherein such a flexibility and such a thermal conductivity can be compatible with each other at a high level.

Even about a formed body as described above, wherein specified graphite powder is dispersed at random in a formed body or wherein graphite particles are compressed under pressure so as to be aligned, the thermal conductivity thereof has not yet been insufficient for high-level thermally conductive properties that have been actually required without interruption.

About the thermally conductive formed body wherein the c axis of the crystal structure of graphite powder in the formed body is oriented in a direction perpendicular to the direction in which heat is conducted, a high thermal conductivity may be obtained. However, about a high-level compatibility between thermal conductivity and flexibility, a sufficient consideration is not necessarily taken into account. According to the producing process thereof, graphite is difficult to expose with a certainly onto the surface; thus, certainty is short for obtaining a high thermal conductivity. Furthermore, about productivity, costs, energy efficiency, and the like, a sufficient consideration is not given.

### DISCLOSURE OF THE INVENTION

An object of the invention is to provide a thermally conductive sheet having both of a high thermal conductivity and a high flexibility. Another object of the invention is to provide a process for producing, without fail, a thermally conductive sheet having both of a high thermal conductivity and a high flexibility advantageously for productivity, costs and energy efficiency. Still another object of the invention is to provide a radiator having a high heat radiating capability. A different object of the invention is to provide a heat spreader, a heat sink, a heat radiating housing, a heat radiating electronic substrate or electric substrate, a heat radiating pipe or heating pipe, a heat radiating luminous body, a semiconductor device, an electronic instrument, or a light emitting device excellent in heat diffusing performance and heat radiating performance.

Accordingly, the invention relates to (1) a thermally conductive sheet, containing: a composition containing:

graphite particles (A) in the form of a scale, an elliptic sphere or a rod, a 6-membered ring plane in a crystal thereof being oriented in the plane direction of the scale, the major axis direction of the elliptic sphere, or the major axis direction of the rod; and

an organic polymeric compound (B) having a Tg of 50° C. or lower,

wherein the plane direction of the scale, the major axis direction of the elliptic sphere, or the major axis direction of the rod of the graphite particles (A) is oriented in the thickness direction of the thermally conductive sheet, the area of the graphite particles (A) exposed onto surfaces of the thermally conductive sheet is 25% or more and 80% or less, and the Ascar C hardness of the sheet is 60 or less at 70° C.

The invention also relates to (2) the thermally conductive sheet according to description (1), wherein the average value of the major diameters of the graphite particles (A) is 10% or more of the thickness of the thermally conductive sheet.

The invention also relates to (3) the thermally conductive sheet according to description (1) or (2), wherein in a particle diameter distribution which is obtained by classifying the graphite particles (A), the amount of the particles having a diameter of ½ or less of the sheet thickness is 50% or less by mass.

The invention also relates to (4) the thermally conductive sheet according to any one of descriptions (1) to (3), wherein the content of the graphite particles (A) is from 10 to 50% by volume of the whole volume of the composition.

The invention also relates to (5) the thermally conductive sheet according to any one of descriptions (1) to (4), wherein the graphite particles (A) are each in the form of a scale, and the plane direction thereof is oriented in the thickness direction of the thermally conductive sheet and in a single direction in the front and rear planes thereof.

The invention also relates to (6) the thermally conductive sheet according to any one of descriptions (1) to (5), wherein the organic polymeric compound (B) is a poly(meth)acrylic acid ester polymeric compound.

The invention also relates to (7) the thermally conductive sheet according to any one of descriptions (1) to (6), wherein the organic polymeric compound (B) includes either or both of butyl acrylate and 2-ethylhexyl acrylate as a copolymerization component, and the amount thereof in the copolymerization composition is 50% or more by mass.

The invention also relates to (8) the thermally conductive sheet according to any one of descriptions (1) to (7), wherein the composition contains 5 to 50% by volume of a flame retardant.

The invention also relates to (9) the thermally conductive sheet according to any one of descriptions (1) to (8), wherein the flame retardant is a phosphoric acid ester compound and is further a liquid material having a solidifying point of 15° C. or lower and a boiling point of 120° C. or higher.

The invention also relates to (10) the thermally conductive sheet according to any one of descriptions (1) to (9), wherein the front surface and the rear surface thereof are covered with protective films different in peeling force, respectively.

The invention also relates to (11) the thermally conductive sheet according to any one of descriptions (1) to (10), wherein the organic polymeric compound (B) has a three-dimensional crosslinked structure.

The invention also relates to (12) the thermally conductive sheet according to any one of descriptions (1) to (11), a single surface or both surface thereof being provided with insulating film.

The invention also relates to (13) a process for producing a thermally conductive sheet, comprising:

subjecting a composition containing:
graphite particles (A) in the form of a scale, an elliptic sphere or a rod, a 6-membered ring plane in a crystal thereof being oriented in the plane direction of the scale, the major axis direction of the elliptic sphere, or the major axis direction of the rod; and
an organic polymeric compound (B) having a Tg of 50° C. or lower,

to roll forming, press forming, extrusion forming, or painting, so as to have a thickness not more than 20 times the average value of the major diameters of the graphite particles (A), thereby yielding a primary sheet wherein the graphite particles (A) are oriented in a direction substantially parallel to the main surfaces;

laminating the primary sheet, thereby yielding a formed body; and

slicing the formed body at an angle of 0 to 30 degrees to any normal line extending on the primary sheet surfaces.

The invention also relates to (14) a process for producing a thermally conductive sheet, comprising:

subjecting a composition containing:
graphite particles (A) in the form of a scale, an elliptic sphere or a rod, a 6-membered ring plane in a crystal thereof being oriented in the plane direction of the scale, the major axis direction of the elliptic sphere, or the major axis direction of the rod; and
an organic polymeric compound (B) having a Tg of 50° C. or lower,

to roll forming, press forming, extrusion forming, or painting, so as to have a thickness not more than 20 times the average value of the major diameters of the graphite particles (A), thereby yielding a primary sheet wherein the graphite particles (A) are oriented in a direction substantially parallel to the main surfaces;

winding the primary sheet around the orientation direction of the graphite particles (A) as an axis and yielding formed body; and

slicing the formed body at an angle of 0 to 30 degrees to any normal line extending on the primary sheet surfaces.

The invention also relates to (15) the process for producing a thermally conductive sheet according to description (13) or (14), wherein the formed body is sliced in the temperature range from the Tg of the organic polymeric compound (B)+30° C. to the Tg−40° C.

The invention also relates to (16) the process for producing a thermally conductive sheet according to any one of descriptions (13) to (15), wherein the slicing of the formed body is performed by use of a slicing member having a flat and smooth board surface having a slit, and a blade protruded from the slit, and

the length of the blade protruded from the slit can be adjusted in accordance with a desired thickness of the thermally conductive sheet.

The invention is also (17) the process for producing a thermally conductive sheet according to description (16), wherein the slicing is performed while the flat and smooth board surface and/or the blade is cooled into a temperature within the range of −80° C. to 5° C.

The invention also relates to (18) the process for producing a thermally conductive sheet according to any one of descriptions (13) to (17), wherein the formed body is sliced into a thickness not more than 2 times the average particle diameter obtained by classifying the graphite particles (A).

The invention also relates to (19) a radiator, wherein a thermally conductive sheet according to any one of descriptions (1) to (12), or a thermally conductive sheet obtained by a producing process according to any one of descriptions (13) to (18) is interposed between a heat generating body and a heat radiating body.

The invention also relates to (20) a heat spreader, wherein a thermally conductive sheet according to any one of descriptions (1) to (12), or a thermally conductive sheet obtained by a producing process according to any one of descriptions (13) to (18) is attached to a formed body which is made of a raw material having a thermal conductivity of 20 W/mK or more and is in the form of a plate or form similar to a plate.

The invention also relates to (21) a heat sink, wherein a thermally conductive sheet according to any one of descriptions (1) to (12), or a thermally conductive sheet obtained by a producing process according to any one of descriptions (13) to (18) is attached to a formed body which is made of a raw material having a thermal conductivity of 20 W/mK or more and is in the form of a bulk or a bulk having a fin.

The invention also relates to (22) a heat radiating housing, wherein a thermally conductive sheet according to any one of descriptions (1) to (12), or a thermally conductive sheet obtained by a producing process according to any one of descriptions (13) to (18) is attached to an inner surface of a box which is made of a raw material having a thermal conductivity of 20 W/mK or more.

The invention also relates to (23) a heat radiating electronic substrate or electric substrate, wherein a thermally conductive sheet according to any one of descriptions (1) to (12), or a thermally conductive sheet obtained by a producing process according to any one of descriptions (13) to (18) is attached to an insulated region of an electronic substrate or electric substrate.

The invention also relates to (24) a heat radiating pipe or heating pipe, wherein a thermally conductive sheet according to any one of descriptions (1) to (12), or a thermally conductive sheet obtained by a producing process according to any one of descriptions (13) to (18) is used in a joint region of heat radiating pipe pieces or heating pipe pieces, and/or a joint region which is to be fitted to an object to be cooled or object to be heated.

The invention also relates to (25) a heat radiating luminous body, wherein a thermally conductive sheet according to any one of descriptions (1) to (12), or a thermally conductive sheet obtained by a producing process according to any one of descriptions (13) to (18) is attached to a back surface area of an electric lamp, a fluorescent light, or an LED.

The invention also relates to (26) a semiconductor device, having a thermally conductive sheet according to any one of descriptions (1) to (12), or a thermally conductive sheet obtained by a producing process according to any one of descriptions (13) to (18), wherein the thermally conductive sheet diffuses heat generated from a semiconductor.

The invention also relates to (27) an electronic instrument, having a thermally conductive sheet according to any one of descriptions (1) to (12), or a thermally conductive sheet obtained by a producing process according to any one of descriptions (13) to (18), wherein the thermally conductive sheet diffuses heat generated from an electronic component.

The invention also relates to (28) a light emitting device, having a thermally conductive sheet according to any one of descriptions (1) to (12), or a thermally conductive sheet obtained by a producing process according to any one of descriptions (13) to (18), wherein the thermally conductive sheet diffuses heat generated from a light emitting element.

### BEST MODE FOR CARRYING OUT THE INVENTION

The thermally conductive sheet of the invention includes a composition containing: graphite particles (A) in the form of a scale, an elliptic sphere or a rod, a 6-membered ring plane in a crystal thereof being oriented in the plane direction of the scale, the major axis direction of the elliptic sphere, or the major axis direction of the rod; and an organic polymeric compound (B) having a Tg of 50° C. or lower.

The form of the graphite particles (A) in the invention is in the form of a scale, an elliptic sphere or a rod. The form of the scale is particularly preferred. If the form of the graphite particles (A) is a spherical or indeterminate form, the composition may be poor in electroconductivity. If the form is a fibrous form, the composition may not be easily formed into a sheet so as to tend to give a poor productivity.

The 6-membered ring plane in the crystal thereof is oriented in the plane direction of the scale, the major axis direction of the elliptic sphere, or the major axis direction of the rod. The orientation can be confirmed by X-ray diffraction measurement. Specifically, the orientation is confirmed by the following method. First, formed is a measurement sample sheet wherein the plane direction of the scale, the major axis direction of the elliptic sphere, or the major axis direction of the rod of graphite particles is oriented in substantially parallel to the plane direction of the sheet or film. In a specific method for preparing the sample sheet, a mixture of 10% or more by volume of graphite particles and a resin is made into a sheet. The “resin” used in this case may use a resin corresponding to the organic polymeric compound (B). If the material to be mixed with the graphite particles is a material about which a peak that hinders X-ray diffraction does not make its appearance, for example, an amorphous resin, the material is sufficient. A material other than resin may be used if the material can be shaped. This sheet is pressed to have a thickness of 1/10 or less of the original thickness thereof. Such pressed sheets are laminated. An operation for crushing the laminate into 1/10 or less in thickness is repeated three times. In the sample sheet prepared by this operation, the graphite particles turn into the state that the plane direction of the scale, the major axis direction of the elliptic sphere, or the major axis direction of the rod of the graphite particles is oriented in substantially parallel to the plane direction of the sheet or film. When a surface of the thus-prepared measurement sample sheet is subjected to X-ray diffraction measurement, the following value becomes a value from 0 to 0.02, which is a value obtained by dividing the height of a peak corresponding to the (110) plane of graphite and making its appearance near 2θ=77° by the height of a peak corresponding to the (002) plane of graphite and making its appearance near 2θ=27°.

From this matter, the wording “the 6-membered ring plane in the crystal thereof being oriented in the plane direction of the scale, the major axis direction of the elliptic sphere, or the major axis direction of the rod” in the invention means the following: a surface of a product obtained by making a composition for thermally conductive sheet such as graphite particles, an organic polymeric compound and the like into a sheet is subjected to X-ray diffraction measurement; the height of a peak corresponding to the (110) plane of graphite and making its appearance near 2θ=77° is then divided by the height of a peak corresponding to the (002) plane of graphite and making its appearance near 2θ=27°; and when the resultant value is from 0 to 0.02, the wording means the state of the graphite particles or composition.

The graphite particles (A) used in the invention may use, for example, in the form of a scale, an elliptic sphere or a rod graphite particles of scaly graphite powder, artificial graphite powder, graphite powder made into thin pieces, acid-treated graphite powder, expanded graphite powder, carbon fiber flakes, or the like.

Particularly preferred is a material that turns easily into scale-form graphite particles when the material is mixed with the organic polymeric compound (B). Specifically, scale-form graphite particles of scaly graphite powder, graphite powder made into thin pieces, or expanded graphite powder are more preferred since the particles are easily oriented and further contact between the particles is also kept with ease so that a high thermal conductivity is easily obtained.

The average value of the major diameters of the graphite particles (A) is not particularly limited, and is preferably from 0.05 to 2 mm, more preferably from 0.1 to 1.0 mm, in particular preferably from 0.2 to 0.5 mm from the viewpoint of an improvement in the thermal conductivity.

The content of the graphite particles (A) is not particularly limited, and is preferably from 10 to 50% by volume, more preferably from 30 to 45% by volume of the whole of the composition. If the content of the graphite particles (A) is less than 10% by volume, the thermal conductivity tends to lower. If the content is more than 50% by volume, sufficient flexibility or adhesiveness tend not to be easily obtained. In the present specification, the content (% by volume) of the graphite particles (A) is a value obtained in accordance with the following equation.

The content (% by volume) of the graphite particles (A)=(Aw/Ad)/((Aw/Ad)+(Bw/Bd)+(Cw/Cd)+ . . . )×100

wherein

Aw: the mass composition (% by weight) of the graphite particles (A),
Bw: the mass composition (% by weight) of the organic polymeric compound (B),
Cw: the mass composition (% by weight) of an optional component (C) other than the above,
Ad: the specific gravity of the graphite particles (A) (any calculation is made in the invention, using 2.25 as Ad),
Bd: the specific gravity of the polymeric compound (B), and
Cd: the specific gravity of the optional component (C) other than the above.

About the organic polymeric compound (B) in the invention, the Tg (glass transition temperature) thereof is 50° C. or lower, preferably from −70 to 20° C., more preferably −60 to 0° C. If the Tg is higher than 50° C., the sheet of the invention may be poor in the flexibility so as to tend to be poor in adhesiveness to a heat generating body and a heat radiating body.

The organic polymeric compound (B) used in the invention is preferably a flexible organic polymeric compound generally called “rubber”, example thereof including: a poly(meth)acrylate polymeric compound made mainly from butyl acrylate, 2-ethylhexyl acrylate, or the like as raw material component (the so-called acrylic rubber); a polymeric compound having, as a main structure, a polydimethylsiloxane structure (the so-called silicone resin); a polymeric compound having, as a main raw material component (the so-called isoprene rubber or natural rubber), a polyisoprene structure; a polymeric compound having, as a main structure, chloroprene (the so-called chloroprene rubber); and a polymeric compound having, as a main structure, polybutadiene structure (the so-called butadiene rubber). Of these compounds, preferred is a poly(meth)acrylate polymeric compound, in particular, a poly (meth)acrylate polymeric compound including either or both of butyl acrylate and 2-ethylhexyl acrylate as a copolymerization component wherein the amount of the component in the copolymerization composition is 50% or more by mass for the following reasons: a high flexibility is easily obtained; the chemical stability and the workability are excellent; the adhesiveness is easily controlled; and the polymeric compound is relatively inexpensive. Moreover, it is preferred from the viewpoint of close adhesion for a long term and film strength that a crosslinked structure is included thereinto as far as in the range that the flexibility is not lost. The crosslinked structure can be included, for example, by causing a compound having plural isocyanate groups to react with a polymer having a —OH group.

The content of the organic polymeric compound (B) is not particularly limited, and is preferably from 10 to 70% by volume, more preferably from 20 to 50% by volume of the whole of the composition.

The thermally conductive sheet of the invention may contain a flame retardant. The flame retardant is not particularly limited, and may contain, for example, a red phosphorus flame retardant, or a phosphoric acid ester flame retardant.

Examples of the red phosphorus flame retardant include pure red phosphorus powder, and others such as red phosphorus covered with a coating which may be of various kinds in order to improve safety or the stability, and red phosphorus made into a master batch. Specific examples thereof include RINKA FR, RINKA FE, RINKA FQ, RINKA FP (trade names) manufactured by RINKAGAKU KOGYO CO., LTD.

Examples of the phosphoric acid ester flame retardant include aliphatic phosphoric acid esters such as trimethyl phosphate, triethyl phosphate, and tributyl phosphate; aromatic phosphoric acid esters such as triphenyl phosphate, tricresyl phosphate, cresyl diphenyl phosphate, trixylenyl phosphate, cresyl-2,6-xylenyl phosphate, tris(t-butylphenyl) phosphate, tris(isopropenylphenyl) phosphate, and triarylisopropyl phosphate; and aromatic condensed phosphoric acid esters such as resorcinol bisdiphenyl phosphate, bisphenol A bis(diphenyl phosphate) and resorcinol bisdixylenyl phosphate. These may be used alone or in combination of two or more thereof. In a case where the flame retardant is a phosphoric acid ester compound and is further a liquid material having a solidifying point of 15° C. or lower and a boiling point of 120° C. or higher, the flame retardancy and the flexibility or tackiness are easily made compatible with each other; thus, the case is preferred. Examples of the phosphoric acid ester flame retardant that is a liquid material having a solidifying point of 15° C. or lower and a boiling point of 120° C. or higher include such as trimethyl phosphate, triethyl phosphate, tricresyl phosphate, trixylenyl phosphate, cresyldiphenyl phosphate, cresyl-2,6-xylenyl phosphate, resorcinol bisdiphenyl phosphate, and bisphenol A bis(diphenyl phosphate).

The content of the flame retardant is not particularly limited, and is preferably from 5 to 50% by volume, more preferably from 10 to 40% by volume of the whole of the composition. When the content of the flame retardant is in the range, a sufficient flame retardancy is favorably expressed and further an advantage is generated from the viewpoint of flexibility. If the content of the flame retardant is less than 5% by volume, a sufficient flame retardancy may not be easily obtained. If the content is more than 50% by volume, the sheet strength tends to lower.

If needed, the following may be appropriately added to the thermally conductive sheet of the invention: a toughness improver such as urethane acrylate; a moisture absorbent such as calcium oxide, or magnesium oxide; an adhesiveness improver such as a silane coupling agent, a titanium coupling agent, or an acid anhydride; a wettability improver such as a nonionic surfactant, or a fluorochemical surfactant; an antifoaming agent such as a silicone oil; an ion trapping agent such as an inorganic ion exchanger.

In the thermally conductive sheet of the invention, the plane direction of the scale, the major axis direction of the elliptic sphere, or the major axis direction of the rod of the graphite particles (A) is oriented in the thickness direction of the thermally conductive sheet. If this orientation is absent, a sufficient thermal conductivity may not be obtained. In a case where the graphite particles (A) are in a scale form and further the plane direction thereof is oriented in the thickness direction of the thermally conductive sheet and a single direction in the front and rear planes, the thermal conductivity and the thermal expansion property have anisotropy in the front and rear planes. Therefore, it is easy to design an allowance about which the control of the heat shielding performance/heat radiating performance toward the side direction of the sheet, or the thermal expansion thereof are considered. This characteristic can be given; thus, the case is preferred.

In the thermally conductive sheet of the invention, the area of the graphite particles (A) exposed onto surfaces of the thermally conductive sheet is 25% or more and 80% or less, preferably form 35 to 75%, more preferably from 40 to 70%. If the area of the graphite particles (A) exposed onto surfaces of the thermally conductive sheet is less than 25%, a sufficient thermal conductivity tends not to be obtained. If the area is more than 80%, the flexibility or the adhesiveness of the thermally conductive sheet tends to be damaged.

In order to set the “area of the graphite particles (A) exposed onto surfaces of the thermally conductive sheet into 25% or more and 80% or less”, it is advisable to blend the above-mentioned preferred graphite particles (A) into an amount of 10 to 50% by volume of the whole of the composition and then form a sheet by a sheet-producing process that will be described later.

In the invention, the wording “oriented in the thickness direction of the thermally conductive sheet” means the following: first, the thermally conductive sheet is cut into an equilateral octagon, and a cross section of each side thereof is observed with an SEM (scanning electron microscope); regarding the cross section of any one of the sides, the angle of the major axis direction of each of any 50 ones out of the graphite particles to the thermally conductive sheet surfaces is measured from the direction in which the particle is seen (when the angle is 90 degrees or more, the supplementary angle thereof is adopted); and a state that the average value of the measured angles ranges from 60 to 90 degrees is realized. The wording “oriented in a single direction in the front and rear planes” means the following state: an SEM is used to observe the front surface of the thermally conductive sheet or a cross section thereof parallel to the front surface; the direction of the dispersed angle of the major axis direction or each of any 50 ones out of the graphite particles is measured, where the major axis direction of each graphite particles is aligned into a substantially single direction each other, (when the angle is 90 degrees or more, the supplementary angle thereof is adopted); and a state that the average value of the measured angles is in the range of 30 degrees is realized.

In the invention, the “area of the graphite particles (A) exposed onto surfaces of the thermally conductive sheet” is an area obtained by: photographing any one of the surfaces with a magnification at which at least three or more out of the graphite particles can be put in the screen; obtaining, from such plural photographs in which the total number of the graphite particles is 30 or more, the average value between the ratios between the area of the seen graphite particles and the area of the sheet; and then making a calculation.

In the thermally conductive sheet of the invention, the Ascar C hardness is 60 or less, preferably 40 or less at 70° C. If the Ascar C hardness at 70° C. is more than 60, the sheet cannot adhere sufficiently to an electronic substrate, such as a semiconductor package or a display, which is a heat generating body, so that heat tends not to be well conducted or thermal stress tends to be insufficiently relieved.

In order to set the Ascar C hardness of the thermally conductive sheet at 70° C. into 60 or less, the organic polymeric compound (B), which has a Tg of 50° C. or lower, is incorporated in an amount of 10 to 70% by volume of the whole of the composition, further preferably in an amount of 5 to 50% by volume.

In the invention, the “Ascar C hardness at 70° C.” is a value obtained by heating a thermally conductive sheet having a thickness of 5 mm or more on a hot plate to set the temperature measured with a surface thermometer to 70° C., and then measuring the hardness with an Ascar hardness meter C-type.

About the thermally conductive sheet of the invention, the average value of the major diameters of the graphite particles (A) is preferably 10% or more of the thermally conductive sheet thickness, more preferably 20% or more thereof. If the average value of the major diameters of the graphite particles (A) is less than 10% of the thermally conductive sheet thickness, the thermal conductivity tends to lower. The upper limit of the average value of the major diameters of the graphite particles (A) relative to the thermally conductive sheet thickness is not particularly limited, and is preferably about 2/√3 of the thermally conductive sheet thickness in order for the graphite particles (A) not to protrude from the thermally conductive sheet.

In the invention, “the average value of the major diameters” refers to a result obtained by using an SEM (scanning electron microscope) to observe a cross section of the thermally conductive sheet in the thickness direction, measuring the major diameters of any 50 ones out of the graphite particles from the direction in which the particles are seen, and calculating the average value.

About the thermally conductive sheet of the invention, in the particle diameter distribution which is obtained by classifying the graphite particles (A), the amount of the particles having a diameter of ½ or less of the sheet thickness is preferably less than 50% by mass, more preferably less than 20% by mass. If the amount of the particles having a diameter of ½ or less of the sheet thickness is 50% or more by mass in the particle diameter distribution which is obtained by classifying the graphite particles (A), the thermal conductivity tends to lower.

In order to obtain the particle diameter distribution of the graphite particles (A) in the invention, the thermally conductive sheet is first immersed in a dissolving solution such as an organic solvent or an alkali solution or the like to dissolve organic materials made mainly of the organic polymeric compound (B). The given solution is filtrated with a filter paper piece having a pore diameter of 4 μm. The remaining graphite particles are sufficiently washed with the dissolving solution. Thereafter, the particles are further sufficiently washed with water in a case where the dissolving solution is an aqueous solution. The solvent or water are dried with a vacuum drier, and then the particles are classified with a sieve to prepare a cumulative weight distribution curve. From this curve, the proportion of the particles having a size of ½ or less of the sheet thickness can be obtained.

When a single surface or both surfaces of the thermally conductive sheet of the invention has tackiness, the tacky surface of the thermally conductive sheet may be covered with a protective film in order to protect the tacky surface before the thermally conductive sheet is used. The material of the protective film may use, for example, a resin such as a polyethylene, polyester, polypropylene, polyethylene terephthalate, polyimide, polyetherimide, polyether naphthalate or methylpentene film, coated paper, coated cloth, or a metal such as aluminum. Two or more protective films made of the materials selected from the above-mentioned materials may be combined with each other to be made into a multilayered film. A protective film is preferably used which has a surface treated with such as a releasing agent of a silicone or silica type or the like. When the front and rear surfaces of the thermally conductive sheet are covered with protective films different in peeling force, respectively, the film in the surface is weak in peeling force may be initially peeled, so as to cause the sheet to adhere to an adherend. In this way, the protective film on the other surface can be restrained from falling out. Thus, the sheet is excellent in workability so as to be preferred.

When an insulating film is attached to either or both of the surfaces thereof, the sheet can be favorably used in a region where electric insulating property is required. When the thermally conductive sheet has both of a protecting film and an insulating film, it is preferred that the protective film is rendered an outermost layer from the viewpoint by protecting the thermally conductive sheet.

The process for producing a thermally conductive sheet of the invention comprises the step of yielding a primary sheet, the step of laminating or winding the primary sheet to yield a formed body, and the step of slicing the formed body.

In the process for producing a thermally conductive sheet of the invention, the following composition is first subjected to roll forming, press forming, extrusion forming, or painting, so as to have a thickness not more than 20 times the average value of the major diameters of the graphite particles (A), thereby yielding a primary sheet wherein the graphite particles (A) are oriented in a direction substantially parallel to the main surfaces: a composition containing graphite particles (A) in the form of a scale, an elliptic sphere or a rod, a 6-membered ring plane in a crystal thereof being oriented in the plane direction of the scale, the major axis direction of the elliptic sphere, or the major axis direction of the rod, and an organic polymeric compound (B) having a Tg of 50° C. or lower.

The composition containing the graphite particles (A) and the organic polymeric compound (B) can be obtained by mixing the two with each other. However, the method for the mixing is not particularly limited. It is allowable to use, for example, a method comprising the steps of dissolving the organic polymeric compound (B) in a solvent, adding thereto the graphite particles (A) and other components, stirring the slurry, and then drying the resultant; a method of roll kneading; or a method of mixing by means of a kneader, a Brabender or an extruder.

Next, the composition is subjected to roll forming, press forming, extrusion forming, or painting, so as to have a thickness not more than 20 times the average value of the major diameters of the graphite particles (A), thereby yielding a primary sheet wherein the graphite particles (A) are oriented in a direction substantially parallel to the main surfaces.

When the composition is formed, the thickness thereof is set to not more than 20 times, preferably 2 to 0.2 times the average value of the major diameters of the graphite particles (A). If the thickness is over 20 times the average value of the major diameters of the graphite particles (A), the graphite particles (A) may be insufficiently oriented, as a result the thermal conductivity of the finally resultant thermally conductive sheet tends to be poor.

When the composition is subjected to roll forming, press forming, extrusion forming, or painting, a primary sheet is formed wherein the graphite particles (A) are oriented in a direction substantially parallel to the main surfaces. However, rolling forming or press forming are preferred since the graphite particles (A) are certainly oriented with ease.

The state that the graphite particles (A) are oriented in a direction substantially parallel to the main surfaces of the sheet refers to a state that the graphite particles (A) are oriented to sleep on the main faces of the sheet. The directions of the graphite particles (A) in the sheet plane are controlled by adjusting the direction in which the composition flows when the composition is formed. In other words, the directions of the graphite particles (A) are controlled by adjusting the direction in which the composition is passed through a rolling roll, in which the composition is extruded, in which the composition is painted, or in which the composition is pressed. Since the graphite particles (A) are basically particles having anisotropy, usually, the directions of the graphite particles (A) are evenly arranged by subjecting the composition to roll forming, press forming, extrusion forming, or painting.

In a case where at the time of the formation of the primary sheet the shape of the composition containing the graphite particles (A) and the organic polymeric compound (B) is a bulk-form material before the composition is formed, it is preferred that the roll forming or press forming is performed in such a manner that the thickness (dp) of the formed primary sheet satisfies the following in connection with the thickness (d0) of the bulk-form material: dp/d0<0.15, or the extrusion forming is performed in such a manner that the thickness (dp′) of the primary sheet satisfies the following in connection with the width (W) thereof: dp′/W<0.15 by adjusting the shape of the extruder outlet corresponding to the sectional shape of the primary sheet. When the formation is attained to satisfy dp/d0<0.15 or dp′/W<0.15, the graphite particles (A) are easily oriented in the direction substantially parallel to the main faces of the sheet.

Next, the primary sheet is laminated or wound to yield a formed body. The method for laminating the primary sheet is not particularly limited, and examples thereof include a method of laminating such plural sheets of the primary sheet onto each other, and a method of folding the primary sheet. At the time of the lamination, the lamination is performed to make the directions of the graphite particles (A) in the sheet plane even. The shape of the primary sheet at the time of the lamination is not particularly limited. For example, when rectangular primary sheets are laminated onto each other, a prismatic formed body is obtained. When circular primary sheets are laminated onto each other, a columnar formed body is obtained.

The method for winding the primary sheet is not particularly limited. It is advisable to wind the primary sheet around the orientation direction of the graphite particles (A) as an axis. The shape of the wound is not particularly limited, and may be, for example, cylindrical or rectangularly tubular.

For convenience of slicing the formed body at an angle of 0 to 30 degrees to any normal line extending from the primary sheet planes in a subsequent step, the pressure when the primary sheet is laminated or the tensile force when the sheet is wound is adjusted to such a weak extent that the sliced faces are crushed so that a sliced area does not fall below a necessary area, and to such a strong extent that regions of the sheet adhere well to each other. Usually, the above-mentioned adjustment makes it possible to give a sufficient adhesive force between the laminated faces or between wound faces. However, if the adhesive force is short, it is allowable to paint a solvent or an adhesive agent and the like thinly onto the primary sheet, and further perform the lamination or winding. The lamination or winding may be performed while the primary sheet is appropriately heated.

Next, the formed body is sliced at an angle of 0 to 30 degrees, preferably 0 to 15 degrees to any normal line extending on the primary sheet surfaces, so as to yield a thermally conductive sheet having a predetermined thickness. If the slicing angle is more than 30 degrees, the thermal conductivity tends to lower. When the formed body is a laminate, the formed body is sliced perpendicularly to the primary-sheet-laminated direction or substantially perpendicular thereto. When the formed body is a wound body, the formed body is sliced perpendicularly to the axis for the winding or substantially perpendicularly thereto. In a case where the formed body is a columnar formed body, wherein circular primary sheets are laminated, the formed body may be sliced into a thin long strip as far as the above-mentioned angle is satisfied.

The method for the slicing is not particularly limited, and examples thereof include such as a multi-blade method, laser processing method, a water jetting method, and a knifing method. The knifing method is preferred since the evenness of the thickness of the thermally conductive sheet is easily kept and no cut scraps are generated. The cutting tool when the formed body is sliced is not particularly limited. However, it is preferred to use a slicing member having a moiety such as a plane, the slicing member having a flat and smooth board surface having a slit, and a blade protruded from the slit wherein the length of the blade protruded from the slit can be adjusted in accordance with a desired thickness of the thermally conductive sheet since the orientation of the graphite particles near the surfaces of the resultant thermally conductive sheet is not easily disturbed and further a thin sheet having a desired thickness is easily formed.

The slicing is performed preferably in the temperature range from the Tg of the organic polymeric compound (B)+30° C. to the Tg−40° C., more preferably in that from the Tg+20° C. to the Tg−20° C. If the slicing temperature is higher than the Tg of the organic polymeric compound (B)+30° C., the formed body may become flexible so that the body is not easily sliced or the orientation of the graphite particles tends to be disturbed. Conversely, if the temperature is lower than the Tg−40° C., the formed body may turn hard and brittle so that the body is not easily sliced or the sheet tends to be easily cracked just after the slicing.

When the flat and smooth board surface and/or the blade of the slicing member is cooled into the range within the range of −80 to 5° C. to slice the formed body, smooth cutting can be attained so that irregularities of the surface are favorably reduced or the disturbance of the orientation structure of the graphite particles is favorably reduced. The temperature is more preferably within the range of −40 to 0° C. If the temperature is lower than −80° C., a large load may be imposed on the slicing member and an energetic inefficiency may be also generated. If the temperature is higher than 5° C., the formed body tends not to be smoothly sliced with ease.

It is preferred that in the slicing of the formed body, the body is sliced into a thickness not more than 2 times the weight-average particle diameter obtained by classifying the graphite particles (A). This is because an effective thermally conductive path is easily formed so that the thermal conductivity of the resultant sheet becomes particularly high. This weight-average molecule diameter is obtained, for example, by classifying used graphite particles with a sieve, measuring the weight of the particles in every particle diameter range, preparing a cumulative weight distribution curve, and gaining the target value of the particle diameter at which the cumulative weight becomes 50% by mass.

The thickness of the thermally conductive sheet is appropriately set in accordance with the usage thereof, and the like. The thickness is preferably within the range of 0.05 to 3 mm, more preferably within the range of 0.1 to 1 mm. If the thickness of the thermally conductive sheet is less than 0.05 mm, the sheet tends to become difficult to handle. If the thickness is more than 3 mm, the heat radiating effect tends to lower. The slice width of the formed body corresponds to the thickness of the thermally conductive sheet, and the slice surface corresponds to a surface of the thermally conductive sheet which is to contact a heat generating body or heat radiating body.

The radiator of the invention is obtained by interposing the thermally conductive sheet of the invention or the thermally conductive sheet obtained by the producing process of the invention between a heat generating body and a heat radiating body. The heat generating body is preferably a body of which surface temperature does not exceed at least 200° C. If the body of which surface temperature may exceed 200° C. is used, the organic polymeric compound in the thermally conductive sheet of the invention or the thermally conductive sheet obtained by the producing process of the invention may decompose; thus, the body is unsuitable, examples of the body including a vicinity of a nozzle of a jet engine, a vicinity of the inside of a kiln, a vicinity of the inside of a blast furnace, a vicinity of the inside of a nuclear reactor, a shell of a spaceship, and the like. The temperature range in which the thermally conductive sheet of the invention or the thermally conductive sheet obtained by the producing process of the invention can be in particular suitably used is within the range of −10 to 120° C., and suitable examples of the heat generating body include such as a semiconductor package, a display, an LED, an electric light, a light emitting element, a luminous body, an electronic component, and a heating pipe.

In the meantime, the heat radiating body is preferably a body made of a raw material utilizing a thermal conductivity of 20 kW/mK or more, for example, a metal such as aluminum or copper, graphite, diamond, aluminum nitride, boron nitride, silicon nitride, silicon carbide, aluminum oxide, or the like. Representative examples of such raw material that can be used, uses a heat spreader, a heat sink, a housing, an electronic substrate, an electric substrate, a heat radiating pipe, and the like.

Examples of the radiator of the invention include a semiconductor device wherein the thermally conductive sheet of the invention or the thermally conductive sheet obtained by the producing process of the invention is used to radiate heat generated from a semiconductor, an electronic instrument wherein the same is used to radiate heat generated from an electronic component, and a light emitting device wherein the same is used to radiate heat generated from a light emitting element.

The radiator of the invention is set up by bringing each surface of the thermally conductive sheet of the invention or the thermally conductive sheet obtained by the producing process of the invention into contact with a heat generating body and a heat radiating body. The method for the contact is not particularly limited as far as the method is a method making it possible to fix the heat generating body, the thermally conductive sheet and the heat radiating body in the state that they are caused to adhere closely to each other sufficiently. The method is preferably a method of screwing them with screws, or a contacting method of sustaining pushing force such as a method of sandwiching them with a clip from the viewpoint of sustaining the close adhesion.

The product wherein the thermally conductive sheet of the invention or the thermally conductive sheet obtained by the producing process of the invention is attached to either one of a heat generating body and a heat radiating body is an excellent article since thermal contact thereof with an adherend is easily kept.

For example, a product wherein the thermally conductive sheet of the invention or the thermally conductive sheet obtained by the producing process of the invention is attached to a formed body that is made of a raw material having a thermal conductivity of 20 W/mK or more and is in a plate form or a form similar to a plate, for example, a tray form is suitable for a heat spreader. A product wherein the same is attached to a formed body that is made of the same raw material and is in the form of a bulk or a bulk having a fin is suitable for a heat sink. A product wherein the same is attached to an inner surface of a box made of the same raw material is suitable for a heat radiating housing. A product wherein the same is attached to an insulated region of an electronic substrate or electric substrate is suitable for a heat radiating electronic substrate or electric substrate. A product wherein the same is used in a joint region of heat radiating pipe pieces or heating pipe pieces at the time of fabricating a heat radiating pipe or heating pipe, and/or a joint region which is to be fitted to an object to be cooled or object to be heated is suitable for a heat radiating pipe or heating pipe. A product wherein the same is attached to a back surface area of an electric lamp, a fluorescent light, or an LED is suitable for a heat radiating luminous body.

### EXAMPLES

The invention will be described by way of the following examples. In each of the examples, thermal conductivity as an index of thermal conduction was obtained by a method described below.

(Measurement of Thermal Conductivity)

A thermally conductive sheet 1 cm in length×1.5 cm in width was sandwiched between a transistor (2SC2233) and a heat radiating aluminum block. While the transistor was pushed, an electric current was sent thereto. The temperature T1 (° C.) of the transistor and the temperature T2 (° C.) of the heat radiating block were measured. From the measured values and the applied electric power W1 (W), the thermal resistance X (° C./W) was calculated in accordance with the following equation.

X=(T1−T2)/W1

From the thermal resistance X (° C./W) from the equation, the thickness d (μm) of the thermally conductive sheet, and a correct coefficient C from a sample having an already-known thermal conductivity, the thermal conductivity Tc (W/mK) was estimated from the following equation.

Tc=C×d/X

### Example 1

The following were sufficiently stirred with a stainless steel spoon: 40 g of an acrylic acid ester copolymer resin (a butyl acrylate/acrylonitrile/acrylic acid copolymer; trade name: HTR-280DR, manufactured by Nagase ChemteX Corporation; weight-average molecular weight: 900000; Tg: −30.9° C.; a 15% by mass solution thereof in toluene; copolymerization amount of butyl acrylate: 86% by mass) as an organic polymeric compound (B); 12 g of scaly expanded graphite powder (trade name: HGF-L, manufactured by Hitachi Chemical Co., Ltd.; average particle diameter: 250 μm) as graphite particles (A); and 8 g of cresyl di2,6-xylenyl phosphate (a phosphate flame retardant, trade name: PX-110, manufactured by DAIHACHI CHEMICAL INDUSTRY CO., LTD.; solidifying point: −14° C.; boiling point: 200° C. or higher) as a flame retardant.

This was painted and extended onto a PET (polyethylene terephthalate) film subjected to releasing treatment, and the resultant was air-dried at room temperature for 3 hours in a draft and then dried in a hot wind drier of 120° C. temperature for 1 hour to yield a composition. The blend proportion by volume of each of the components in the whole of the composition was calculated from the specific gravity of each of the components. As a result, the blend proportion of the graphite particles (A) were 30% by volume, that of the organic polymeric compound (B) were 31.2% by volume, and that of the flame retardant were 38.8% by volume, respectively.

A proportion of this composition was made round into the form of a sphere having a diameter of 1 cm, and then made into the form of a sheet having a thickness of 0.5 mm with a small-sized press. This was cut into 20 sheets, and the sheets were laminated onto each other. The laminate was again pressed in the same manner. This operation was further repeated once to yield a sheet. A surface thereof was analyzed by X-ray diffraction. A peak corresponding to the (110) plane of graphite was unable to be found out near 2θ=77°, so that it was able to verified that in the used expanded graphite powder (HGF-L), the “6-membered ring plane of the crystal was oriented in the plane direction of the scale”.

One gram of this composition was made round into the form of a bulk having a height of 6 mm, and then sandwiched between PET films subjected to releasing treatment. A press having a tool plane 5 cm×10 cm in size was used to press the resultant under conditions that the tool pressure was 10 MPa and the tool temperature was 170° C. for 20 seconds to yield a primary sheet 0.3 mm in thickness. This operation was repeated to produce many primary sheets.

Some of the resultant primary sheets were cut into pieces 2 cm×2 cm in size with a cutter, and then 37 out of the resultant cut pieces were laminated onto each other so as to make the directions of the graphite particles even. The laminate was lightly pressed by hand, so as to cause the sheets to adhere to each other, thereby yielding a formed body 1.1 cm in thickness. Next, this formed body was cooled to −15° C. with dry ice, and then a planer (protruded length of its blade from its slit: 0.34 mm) was used to slice one of the laminate cross sections 1.1 cm×2 cm in size (slice at an angle of 0 degree to any normal line extending the primary sheet surfaces), thereby yielding a thermally conductive sheet (I), 1.1 cm in length×2 cm in width×0.58 mm in thickness.

An SEM (scanning electron microscope) was used to observe the cross section of the thermally conductive sheet (I). About any 50 ones out of the graphite particles, the major diameters thereof were measured from the direction in which the particles were seen, and then the average value thereof was calculated out. As a result, the average value of the major diameters of the graphite particles was 254 μm.

The SEM (scanning electron microscope) was used to observe the cross section of the thermally conductive sheet (I). About any 50 ones out of the graphite particles, the angles of the plane direction of the scales to the surfaces of the thermally conductive sheet were measured from the direction in which the particles were seen, and then the average value thereof was calculated out. As a result, the value was 90 degrees. It was verified that the plane direction of the scales of the graphite particles was oriented to the thickness direction of the thermally conductive sheet.

In the thermally conductive sheet (I), one of the sheet surfaces was photographed with a magnification at which at least three or more out of the graphite particles were put in the screen. From each of the resultant photographs with the number where the total number of the photographed graphite particles is 30 or more, the ratio of the area of the seen graphite particles to the area of the sheet was obtained, and then the average value of the resultant ratios was obtained. As a result, the area of the graphite particles exposed onto the sheet surfaces was 30%.

The thermally conductive sheet (I) was heated on a hot plate in such a manner that the temperature measured with a surface thermostat would be 70° C., and then measured with an Ascar hardness meter C type. As a result, the Ascar C hardness at 70° C. was 20. Ethyl acetate was used as a solvent to take out the graphite particles by the above-mentioned method. In the particle diameter distribution obtained by classifying the graphite particles, the amount of the particles having a size of ½ or less of the sheet thickness, that is, 0.29 mm or less was 70% by mass.

The thermal conductivity of this thermally conductive sheet (I) was measured. As a result, a good value of 65 W/mK was shown. The adhesiveness of the thermally conductive sheet (I) to the transistor and the heat radiating aluminum block was also good.

### Example 2

The following were stirred: 40 g of a butyl acrylate-methyl methacrylate block copolymer (trade name: LA2140, manufactured by KURARAY CO., LTD.; Tg: −22° C.; copolymerization amount of butyl acrylate: 77% by mass), and 120 g of a butyl acrylate-methyl methacrylate block copolymer (trade name: LA1114, manufactured by KURARAY CO., LTD.; Tg: −40° C.; copolymerization amount of butyl acrylate: 93% by mass) as organic polymeric compounds (B); 360 g of scaly expanded graphite powder (trade name: HGF-L, manufactured by Hitachi Chemical Co., Ltd.; average particle diameter: 250 μm) as graphite particles (A); and 20 g of red phosphorus (trade name: RINKA FR 120, manufactured by RINKAGAKU KOGYO CO., LTD.), and 50 g of cresyl di2,6-xylenyl phosphate (a phosphate flame retardant, trade name: PX-110; manufactured by DAIHACHI CHEMICAL INDUSTRY CO., LTD.; solidifying point: −14° C.; boiling point: 200° C. or higher) as flame retardants; and 280 g of mixed pellets of a butyl acrylate-methyl methacrylate block copolymer and aluminum hydroxide (trade name: LA FK010, manufactured by KURARAY CO., LTD.; Tg of the polymer fraction: −22° C.; copolymerization amount of butyl acrylate in the polymer fraction: 77% by mass; ratio (by volume) of the polymer to aluminum hydroxide=55:45). The mixture was then kneaded with a 2-roll machine (testing roll machine (8×20T rolls), manufactured by Kansai roll co., ltd.) at 100° C. to yield a composition in the form of a kneaded sheet.

The blend proportion by volume of each of the components in the whole of the composition was calculated from the specific gravity of each of the composition. As a result, the blend proportion of the graphite particles (A) were 30.3% by volume, that of the organic polymeric compounds (B) were 45.6% by volume, and that of the flame retardants were 24.1% by volume, respectively.

The resultant kneaded sheet was cut into pieces about 2 to 3 mm square, so as to be made into the form of pellets. The pellets were extruded into the form of a sheet 60 mm in width and 2 mm in thickness at 170° C. by use of a Laboplast mill MODEL 20C200 manufactured by Toyo Seiki Seisaku-sho, Ltd. In this way, a primary sheet was yielded.

The resultant primary sheet was cut into pieces 2 cm×2 cm in size with a cutter. Acetone was painted thinly onto the sheet surfaces, and then six out of the resultant cut pieces were laminated onto each other. The laminate was lightly pressed by hand, so as to cause the sheets to adhere to each other, thereby yielding a formed body 1.2 cm in thickness. Next, this formed body was cooled to −5° C. with dry ice, and then a planer (protroded length of its blade from its slit: 0.33 mm) was used to slice one of the laminate cross sections 1.2 cm×2 cm in size (slice at an angle of 0 degree to any normal line extending the primary sheet surfaces), thereby yielding a thermally conductive sheet (II), 1.2 cm in length×2 cm in width×0.55 mm in thickness.

Subsequently, the same operations as in Example 1 were performed to obtain the properties of the thermally conductive sheet (II). The average value of the major diameters of the graphite particles was 252 μm. An SEM (scanning electron microscope) was used to observe a cross section of the thermally conductive sheet (II). About any 50 ones out of the graphite particles, the angles of the plane direction of the scales to the surfaces of the thermally conductive sheet were measured from the direction in which the particles were seen, and then the average value thereof was calculated out. As a result, the value was 88 degrees. It was verified that the plane direction of the scales of the graphite particles was oriented to the thickness direction of the thermally conductive sheet. The area of the graphite particles exposed onto the sheet surfaces was 29%. The Ascar C hardness at 70° C. was 38. Ethyl acetate was used as a solvent to take out the graphite particles by the above-mentioned method. In the particle diameter distribution obtained by classifying the graphite particles, the amount of the particles having a size of ½ or less of the sheet thickness, that is, 0.275 mm or less was 75% by mass.

The same operation as in Example 1 was performed to measure the thermal conductivity of the thermally conductive sheet (II). As a result, a good value of 7.5 W/mK was shown. The adhesiveness of the thermally conductive sheet (II) to the transistor and the heat radiating aluminum block was also good.

### Example 3

Pieces 2 mm×2 cm in size cut out from a primary sheet yielded in the same manner as in Example 1 were laminated onto several number of pieces to yield a rectangular rod 2 mm square×2 cm. Separately, a large number of pieces 2 cm×5 cm in size cut out from a primary sheet yielded in the same manner as in Example 1 were prepared. One of the sides 2 cm in length of one of the pieces was caused to adhere to the rectangular rod, and the piece was wound around the side as a center. While the piece was pressed by hand in order to cause regions of the primary sheet to adhere to each other, the winding was performed. Next, another of the pieces was further wound around the outside of the wound. Subsequently, the same operation was repeated until the diameter exceeded 2 cm.

A planer (protruded length of its blade from its slit: 0.34 mm) was used to slice one of the winding cross sections, in the form of a spiral having a diameter of a little more than 2 cm, of the resultant wound in the same manner as in Example 1 (slice at an angle of 0 degree to any normal line extending the primary sheet surfaces), thereby yielding a sheet 0.60 mm in thickness. This sheet was punched out with a hand punch, 1 cm×2 cm in size, to yield a thermally conductive sheet (III) 1.0 cm in length×2 cm in width×0.60 mm in thickness.

Subsequently, the same operations as in Example 1 were performed to obtain the properties of the thermally conductive sheet (III). The average value of the major diameters of the graphite particles was 250 μm. An SEM (scanning electron microscope) was used to observe a cross section of the thermally conductive sheet (III). About any 50 ones out of the graphite particles, the angles of the plane direction of the scales to the surfaces of the thermally conductive sheet were measured from the direction in which the particles were seen, and then the average value thereof was calculated out. As a result, the value was 90 degrees. It was verified that the plane direction of the scales of the graphite particles was oriented to the thickness direction of the thermally conductive sheet. The area of the graphite particles exposed onto the sheet surfaces was 30%. The Ascar C hardness at 70° C. was 20. Ethyl acetate was used as a solvent to take out the graphite particles by the above-mentioned method. In the particle diameter distribution obtained by classifying the graphite particles, the amount of the particles having a size of ½ or less of the sheet thickness, that is, 0.3 mm or less was 72% by mass.

The same operation as in Example 1 was performed to measure the thermal conductivity of the thermally conductive sheet (III). As a result, a good value of 62 W/mK was shown. The adhesiveness of the thermally conductive sheet (III) to the transistor and the heat radiating aluminum block was also good.

### Example 4

The following were stirred: 251.9 g of a butyl acrylate-ethyl acrylate-hydroxyethyl methacrylate copolymer (trade name: HTR-811DR, manufactured by Nagase ChemteX Corporation; weight-average molecular weight: 420000; Tg: −43° C.; copolymerization amount of butyl acrylate: 76% by mass) as an organic polymeric compound (B); 542.5 g of scaly expanded graphite powder (powder classified into the range of 420 to 1000 μm; trade name: HGF-L, manufactured by Hitachi Chemical Co., Ltd.; average particle diameter: 430 μm) as graphite particles (A); and 213.1 g of an aromatic condensed phosphate flame retardant, (trade name: CR-741, manufactured by DAIHACHI CHEMICAL INDUSTRY CO., LTD.; solidifying point: 4 to 5° C., boiling point: 200° C. or higher) as a flame retardant. The mixture was then kneaded with a 2-roll machine (testing roll machine (8×20T rolls), manufactured by Kansai roll co., ltd.) at 80° C. to yield a composition in the form of a kneaded sheet.

From the resultant kneaded sheet, a primary sheet 1 mm in thickness was yielded by means of the same machine as in Example 2 at the same temperature as therein. This sheet was cut into pieces 4 cm×20 cm in size with a cutter, and then 40 out of the resultant cut pieces were laminated onto each other. The laminate was lightly pressed by hand, so as to cause the sheets to adhere to each other. Furthermore, a heavy stone 3 kg in weight was put on the laminate, and then the laminate was treated in a hot wind drier of 120° C. temperature for 1 hour to cause the sheets to adhere sufficiently to each other. In this way, a formed body 4 cm in thickness was yielded. Next, this formed body was cooled to −20° C. with dry ice, and then a super-finishing planer board (trade name: SUPER MECA, manufactured by MARUNAKA TEKKOSYO INC. (protruded length of its blade from its slit: 0.19 mm)) was used to slice one of the laminate cross sections 4 cm×20 cm in size (slice at an angle of 0 degree to any normal line extending the primary sheet surfaces), thereby yielding a thermally conductive sheet (IV), 4 cm in length×20 cm in width×0.25 mm in thickness.

Subsequently, the same operations as in Example 1 were performed to obtain the properties of the thermally conductive sheet (IV). The average value of the major diameters of the graphite particles was 200 μm. An SEM (scanning electron microscope) was used to observe a cross section of the thermally conductive sheet (IV). About any 50 ones out of the graphite particles, the angles of the plane direction of the scales to the surfaces of the thermally conductive sheet were measured from the direction in which the particles were seen, and then the average value thereof was calculated out. As a result, the value was 88 degrees. It was verified that the plane direction of the scales of the graphite particles was oriented to the thickness direction of the thermally conductive sheet. The area of the graphite particles exposed onto the sheet surfaces was 60%. The Ascar C hardness at 70° C. was 50. Ethyl acetate was used as a solvent to take out the graphite particles by the above-mentioned method. In the particle diameter distribution obtained by classifying the graphite particles, the amount of the particles having a size of ½ or less of the sheet thickness, that is, 0.125 mm or less was 25% by mass.

The same operation as in Example 1 was performed to measure the thermal conductivity of the thermally conductive sheet (IV). As a result, a good value of 102 W/mK was shown. The adhesiveness of the thermally conductive sheet (IV) to the transistor and the heat radiating aluminum block was also good.

A laminator (LMP-350EX manufactured by LAMI CORPORATION INC.) was used at room temperature to cause a PET film A31 (film thickness: 38 μm) manufactured by Teijin DuPont Films Japan Limited to adhere, as a protective film, onto one of the surfaces of the thermally conductive sheet (IV), and cause an A53 (film thickness: 50 μm) manufactured by the same to adhere, as a protective film, onto the other surface of the thermally conductive sheet (IV). About these protective films, peeling treatments for the surfaces thereof were different; the A31<the A53 in peeling force. A press cutter (M model, manufactured by Ohshima Kogyo Kabushiki Kaisha) was used to punch out the sheet including the PET films into a shape 3 cm square, wherein the radius of the corners was 1 mm. In this way, the sheet was made into a form that the sheet would easily be used. Separately, a heat spreader (tray-shaped and made of copper) of a CPU Core2 Duo E4300 manufactured by Intel Corporation was peeled off with a cutter, and further a phase change sheet adhering to the rear surface thereof was wiped off. Furthermore, the heat spreader was sufficiently washed with acetone to prepare a heat spreader for CPU. The A31 was first peeled off, and the thermally conductive sheet (IV), wherein one of the surfaces had the A53, was caused to adhere onto the rear surface (the side to which chips were to be attached) of the heat spreader, so as to form a thermally conductive sheet (IV) attached heat spreader for CPU, wherein the sticky surface was protected by the A53. At the time of peeling one of the protective films, the opposite surface was not peeled. Thus, the workability was good.

A sample for estimating the ability of the heat spreader for CPU was prepared by a method described below. The protective film (A53) was peeled off, and then a steel plate 3 cm square×0.8 mm thick was caused to adhere onto the sheet under a pressure of 50 Kgf at 80° C. Separately, a heat spreader of a CPU Core2 Duo E4300 manufactured by Intel Corporation was prepared in the same way. Between the rear surface thereof and the copper plate 3 cm square×0.8 mm thick was sandwiched a 0.2 mm metallic indium sheet. The resultant was pressed under a pressure of 50 Kgf at 160° C. to form a sample. The metallic indium sheet is a material used generally for thermal conduction for heat spreader for CPU, but has no stickiness; thus, the sheet was not easily fixed in position, and a high temperature was required for the melt-bonding thereof. The thermal resistance between the upper and lower surfaces of each of these samples was evaluated with the device described in the above-mentioned description (Measurement of Thermal Conductivity), and the resultant resistances were compared. As a result, the thermal resistance of the sample wherein the thermally conductive sheet (IV) was used was 0.35° C./W, which was lower than 45° C./W, which was that of the sample wherein the indium sheet was used. Thus, it was understood that about a heat spreader for CPU to which the thermally conductive sheet (IV) is attached, thermal contact is easily attached and thus this heat spreader has a high ability.

### Example 5

To the same blend materials as in Example 4 was added 8.3 g of polyisocyanate (COLONATE HL, manufactured by Nippon Polyurethane Industry Co., Ltd.; NCO content: 12.3 to 13.3%; a 75% solution thereof in ethyl acetate). Subsequently, a composition in the form of a kneaded sheet was yielded in the same way.

The yielded kneaded sheet was pushed and crushed by means of a roller press of 100° C. temperature to yield a primary sheet 1 mm in thickness. This sheet was cut into pieces 4 cm×20 cm in size with a cutter, and then 40 out of the resultant cut pieces were laminated onto each other. The laminate was lightly pressed by hand, so as to cause the sheets to adhere to each other. Furthermore, a heavy stone 3 kg in weight was put on the laminate, and then the laminate was treated in a hot wind drier of 150° C. temperature for 1 hour to cause the sheets to adhere sufficiently to each other and simultaneously advance crosslinking reaction. In this way, a formed body 4 cm in thickness was yielded. Next, this formed body was sliced by means of the same machine as in Example 4; however, at the time of the slicing, dry ice was put on the planer board to cool the blade and the board surface to −30° C. As a result, the slicing turned smooth so that the formed body could be cut into a thin piece. Thus, a thermally conductive sheet (V) 4 cm in length×20 cm in width×0.08 mm in thickness was yielded.

Subsequently, the same operations as in Example 1 were performed to obtain the properties of the thermally conductive sheet (V). The average value of the major diameters of the graphite particles was 200 μm. An SEM (scanning electron microscope) was used to observe a cross section of the thermally conductive sheet (V). About any 50 ones out of the graphite particles, the angles of the plane direction of the scales to the surfaces of the thermally conductive sheet were measured from the direction in which the particles were seen, and then the average value thereof was calculated out. As a result, the value was 88 degrees. It was verified that the plane direction of the scales of the graphite particles was oriented to the thickness direction of the thermally conductive sheet. The area of the graphite particles exposed onto the sheet surfaces was 60%. The Ascar C hardness at 70° C. was 59.

The same operation as in Example 1 was performed to measure the thermal conductivity of the thermally conductive sheet (V). As a result, a good value of 80 W/mK was shown. The adhesiveness of the thermally conductive sheet (V) to the transistor and the heat radiating aluminum block was also good.

### Comparative Example 1

The primary sheet formed in Example 1 was used as it was, and evaluated as a thermally conductive sheet (VI).

Subsequently, the same operations as in Example 1 were performed to obtain the properties of the thermally conductive sheet (VI). The average value of the major diameters of the graphite particles was 252 μm. An SEM (scanning electron microscope) was used to observe a cross section of the thermally conductive sheet (VI). About any 50 ones out of the graphite particles, the angles of the plane direction of the scales to the surfaces of the thermally conductive sheet were measured from the direction in which the particles were seen, and then the average value thereof was calculated out. As a result, the value was 0 degrees. Thus, the plane direction of the scales of the graphite particles was not oriented to the thickness direction of the thermally conductive sheet. The area of the graphite particles exposed onto the sheet surfaces was 25%. The Ascar C hardness at 70° C. was 20.

The same operation as in Example 1 was performed to measure the thermal conductivity of the thermally conductive sheet (VI). As a result, a low value of 1.2 W/mK was shown. The adhesiveness of the thermally conductive sheet (VI) to the transistor and the heat radiating aluminum block was good.

### Comparative Example 2

An expanded graphite press sheet (trade name: CARBOFIT, manufactured by Hitachi Chemical Co., Ltd.; thickness: 0.1 mm; density: 1.15 g/cm³) was cut into pieces 2 cm square, and 100 out of the pieces were caused to adhere onto each other with an epoxy adhesive (trade name: BOND QUICK 5, manufactured by Konishi Co., Ltd.) to yield a formed body 1.1 cm in thickness. Next, one of the laminate cross sections (1.1 cm×2 cm) of this formed body was sliced with a cutter to yield a thermally conductive sheet (VII) 1.1 cm in length×2 cm in width×1.5 mm in thickness.

Subsequently, the same operations as in Example 1 were performed to obtain the properties of the thermally conductive sheet (VII). An SEM (scanning electron microscope) was used to observe a cross section of the thermally conductive sheet (V). The graphite was seen in a continuous state, and the graphite was not evidently recognized as particles. However, the average value of the angles of the major axis direction of the graphite region to the surfaces of the thermally conductive sheet was 90 degrees. Thus, it was verified that the graphite particles were oriented to the thickness direction of the thermally conductive sheet. The area of the graphite particles exposed onto the sheet surfaces was 61%. Almost all of the other area was made of voids. The Ascar C hardness at 70° C. was 100 or more.

The same operation as in Example 1 was performed to measure the thermal conductivity of the thermally conductive sheet (VII). As a result, the adhesiveness of the sheet was poor, so that the measured value was unstable in the range of 1 to 40 W/mK. It was judged that the thermal conductivity was practically poor.

### Comparative Example 3

A thermally conductive sheet (VIII) 1.1 cm in length×2 cm in width×0.56 mm in thickness was yielded by the same operations as in Example 1 except that 14 g of a methyl methacrylate polymer (trade name: METHYL METHACRYLATE POLYMERIZE, manufactured by Wako Pure Chemical Industries, Ltd.; Tg: 100° C.) was used as an organic polymeric compound (B) instead of 40 g of the acrylic acid ester copolymer resin (butyl acrylate/acrylonitrile/acrylic acid copolymer; trade name: HTR-280DR, manufactured by Nagase ChemteX Corporation; weight-average molecular weight: 900000, Tg: −30.9° C.; 15% by mass solution thereof in toluene), and cresyl di2,6-xylenyl phosphate as the flame retardant was not used.

The blend proportion by volume of each of the components in the whole of the composition was calculated from the specific gravity of each of the components. As a result, the blend proportion of the graphite particles (A) were 31.3% by volume, and that of the organic polymeric compound (B) were 68.7% by volume, respectively.

Subsequently, the same operations as in Example 1 were performed to obtain the properties of the thermally conductive sheet (VIII). The average value of the major diameters of the graphite particles was 254 μm. An SEM (scanning electron microscope) was used to observe a cross section of the thermally conductive sheet (VIII). About any 50 ones out of the graphite particles, the angles of the plane direction of the scales to the surfaces of the thermally conductive sheet were measured from the direction in which the particles were seen, and then the average value thereof was calculated out. As a result, the value was 90 degrees. It was verified that the plane direction of the scales of the graphite particles was oriented to the thickness direction of the thermally conductive sheet. The area of the graphite particles exposed onto the sheet surfaces was 30%. The Ascar C hardness at 70° C. was over 100.

The same operation as in Example 1 was performed to measure the thermal conductivity of the thermally conductive sheet (VIII). As a result, the adhesiveness of the sheet was poor, so that the measured value was unstable in the range of 0.5 to 20 W/mK. It was judged that the thermal conductivity was practically poor.

### Comparative Example 4

A thermally conductive sheet (IX) 1.1 cm in length×2 cm in width×0.56 mm in thickness was yielded by the same operations as in Example 1 except that spherical natural graphite (average particle diameter: 20 μm) was used as graphite particles (A) instead of the scaly expanded graphite powder (trade name: HGF-L, manufactured by Hitachi Chemical Co., Ltd.; average particle diameter: 250 μm).

The blend proportion by volume of each of the components in the whole of the composition was calculated from the specific gravity of each of the components. As a result, the blend proportion of the graphite particles (A) were 30% by volume, that of the organic polymeric compound (B) were 31.2% by volume, and that of the flame retardant were 38.8% by volume, respectively.

Subsequently, the same operations as in Example 1 were performed to obtain the properties of the thermally conductive sheet (IX). The average value of the major diameters of the graphite particles was 22 μm. The angle of the major axis direction of the graphite particles to the surfaces of the thermally conductive sheet was unclear, so that the angle was not easily specified. The orientation thereof into the thickness direction of the sheet was not recognized. The area of the graphite particles exposed onto the sheet surfaces was 30%. The Ascar C hardness at 70° C. was 18.

The same operation as in Example 1 was performed to measure the thermal conductivity of the thermally conductive sheet (IX). As a result, a low value of 1.2 W/mK was shown. The adhesiveness of the thermally conductive sheet (IX) to the transistor and the heat radiating aluminum block was good.

### INDUSTRIAL APPLICABILITY

The thermally conductive sheet according to the description (1) has both of a high thermal conductivity and a high flexibility to be suitable for heat radiation. The thermally conductive sheet according to any one of the descriptions (2) to (4) can attain a higher thermal conductivity and a higher flexibility as well as the sheet produces the advantageous effect of the invention according to the description (1). The thermally conductive sheet according to the description (5) has an anisotropy in thermal conductivity and thermal expansion property in the front and rear surfaces so as to be characterized in that an allowance is easily designed about which the control of the heat shielding performance/heat radiating performance towards the sides of the sheet or the thermal expansion thereof are considered as well as the sheet produces the advantageous effect of the invention according to any one of the descriptions (1) to (4). The thermally conductive sheet according to the description (6) can attain a still higher flexibility and is further advantageous for productivity or costs as well as the sheet produces the advantageous effect of the invention according to any one of the descriptions (1) to (5). The thermally conductive sheet according to the description (7) can attain a still higher flexibility and is further excellent in the balance between chemical stability and costs as well as the sheet produces the advantageous effect of the invention according to any one of the descriptions (1) to (6). The thermally conductive sheet according to the description (8) has flame retardancy as well as the sheet produces the advantageous effect of the invention according to any one of the descriptions (1) to (7). The thermally conductive sheet according to the description (9) is excellent in compatibility between flame retardancy and flexibility or tackiness as well as the sheet produces the advantageous effect of the invention according to any one of the descriptions (1) to (8). The thermally conductive sheet according to the description (10) is excellent in workability when the sheet is attached as well as the sheet produces the advantageous effect of the invention according to any one of the descriptions (1) to (9). The thermally conductive sheet according to the description (11) can maintain adhesiveness over a long term and can attain a high film strength as well as the sheet produces the advantageous effect of the invention according to any one of the descriptions (1) to (10). The thermally conductive sheet according to the description (12) has an advantage that the sheet can be used for an article or portion for which electric non-conductance is required, such as a vicinity of an electronic/electric circuit, as well as the sheet produces the advantageous effect of the invention according to any one of the descriptions (1) to (11).

The thermally-conductive-sheet-producing processes according to the descriptions (13) and (14) make it possible to produce a thermally conductive sheet having a high thermal conductivity and a high flexibility certainly and advantageously for productivity, costs and energy efficiency. The thermally-conductive-sheet-producing process according to the description (15) makes it possible to produce a sheet-form in such a manner that the oriented structure of graphite is less disturbed and the graphite is certainly exposed onto the surfaces so that a thermally conductive sheet having a high thermal conductivity can be produced as well as the process produces the advantageous effect of the invention according to the descriptions (13) and (14). The thermally-conductive-sheet-producing process according to the description (16) makes it possible to produce a thin sheet easily to reduce the thermal resistance in the thickness direction, so that a higher thermal conductivity is easily obtained, and further makes it possible to cause cut scraps not to be generated, so as to make material-loss very small as well as the process produces the advantageous effect of the invention according to any one of the descriptions (13) to (15). The thermally-conductive-sheet-producing process according to the description (17) makes it possible to slice the formed body smoothly so as to reduce irregularities in the surfaces, thereby giving a still higher thermal conductivity easily, and so as to slice the formed body more thinly as well as the process produces the advantageous effect of the invention according to any one of the descriptions (13) to (16). The thermally-conductive-sheet-producing process according to the description (18) effectively attains the formation of a thermally conductive path made of the graphite particles and penetrating the front and rear surfaces so that a high thermal conductivity is easily obtained as well as the process produces the advantageous effect of the invention according to any one of the descriptions (13) to (17).

The radiator according to the description (19) has a high heat radiating capability. The heat spreader according to the description (20) can certainly keep thermal contact with an adherend with ease, so as to be excellent in heat diffusibility. The heat sink according to the description (21) can certainly keep thermal contact with an adherend with ease, so as to be excellent in heat radiating performance. The heat radiating housing according to the description (22) can certainly keep thermal contact with contents with ease, so as to be excellent in heat radiating performance. The heat radiating electronic substrate or electric substrate according to the description (23) can certainly keep thermal contact with a semiconductor device or the like that becomes a heat source, or a housing, or the like that becomes a heat radiating body with ease, so as to be excellent in heat radiating performance. The heat radiating pipe or heating pipe according to the description (24) can certainly keep thermal contact with a joint region, or an object to be cooled or object to be heated with ease, so as to be excellent in heat radiating performance or heating performance. The heat radiating luminous body according to the description (25) can certainly keep thermal contact with a backside adherend with ease, so as to be excellent in heat radiating performance. The semiconductor device according to the description (26) is excellent in the performance of radiating heat generated from a semiconductor. The electronic instrument according to the description (27) is excellent in the performance of radiating heat generated from an electronic component. The light emitting device according to the description (28) is excellent in the performance of radiating heat generated from a light emitting element.

1. A thermally conductive sheet, including a composition containing:
graphite particles (A) in the form of a scale, an elliptic sphere or a rod, a 6-membered ring plane in a crystal thereof being oriented in the plane direction of the scale, the major axis direction of the elliptic sphere, or the major axis direction of the rod; and
an organic polymeric compound (B) having a Tg of 50° C. or lower,
wherein the plane direction of the scale, the major axis direction of the elliptic sphere, or the major axis direction of the rod of the graphite particles (A) is oriented in the thickness direction of the thermally conductive sheet, the area of the graphite particles (A) exposed onto surfaces of the thermally conductive sheet is 25% or more and 80% or less, and the Ascar C hardness of the sheet is 60 or less at 70° C.

2. The thermally conductive sheet according to claim 1, wherein the average value of the major diameters of the graphite particles (A) is 10% or more of the thickness of the thermally conductive sheet.

3. The thermally conductive sheet according to claim 1, wherein in a particle diameter distribution which is obtained by classifying the graphite particles (A), the amount of the particles having a diameter of ½ or less of the sheet thickness is less than 50% by mass.

4. The thermally conductive sheet according to claim 1, wherein the content of the graphite particles (A) is from 10 to 50% by volume of the whole of the composition.

5. The thermally conductive sheet according to claim 1, wherein the graphite particles (A) are each in the form of a scale, and the plane direction thereof is oriented in the thickness of the thermally conductive sheet and in a single direction in the front and rear planes thereof.

6. The thermally conductive sheet according to claim 1, wherein the organic polymeric compound (B) is a poly(meth)acrylic acid ester polymeric compound.

7. The thermally conductive sheet according to claim 1, wherein the organic polymeric compound (B) includes either or both of butyl acrylate and 2-ethylhexyl acrylate as a copolymerization component, and the amount thereof in the copolymerization composition is 50% or more by mass.

8. The thermally conductive sheet according to claim 1, wherein the composition contains 5 to 50% by volume of a flame retardant.

9. The thermally conductive sheet according to claim 8, wherein the flame retardant is a phosphoric acid ester compound and is further a liquid material having a solidifying point of 15° C. or lower and a boiling point of 120° C. or higher.

10. The thermally conductive sheet according to claim 1, wherein the front surface and the rear surface thereof are covered with protective films different from each other in peeling force, respectively.

11. The thermally conductive sheet according to claim 1, wherein the organic polymeric compound (B) has a three-dimensional crosslinked structure.

12. The thermally conductive sheet according to claim 1, a single surface or both surface thereof being provided with an insulating film.

13. A process for producing a thermally conductive sheet, comprising:
subjecting a composition containing:
graphite particles (A) in the form of a scale, an elliptic sphere or a rod, a 6-membered ring plane in a crystal thereof being oriented in the plane direction of the scale, the major axis direction of the elliptic sphere, or the major axis direction of the rod; and
an organic polymeric compound (B) having a Tg of 50° C. or lower,
to roll forming, press forming, extrusion forming, or painting, so as to have a thickness not more than 20 times the average value of the major diameters of the graphite particles (A), thereby yielding a primary sheet wherein the graphite particles (A) are oriented in a direction substantially parallel to the main surfaces;
laminating the primary sheet, thereby yielding a formed body; and
slicing the formed body at an angle of 0 to 30 degrees to any normal line extending on the primary sheet surfaces.

14. A process for producing a thermally conductive sheet, comprising:
subjecting a composition containing:
graphite particles (A) in the form of a scale, an elliptic sphere or a rod, a 6-membered ring plane in a crystal thereof being oriented in the plane direction of the scale, the major axis direction of the elliptic sphere, or the major axis direction of the rod; and
an organic polymeric compound (B) having a Tg of 50° C. or lower,
to roll forming, press forming, extrusion forming, or painting, so as to have a thickness not more than 20 times the average value of the major diameters of the graphite particles (A), thereby yielding a primary sheet wherein the graphite particles (A) are oriented in a direction substantially parallel to the main surfaces;
winding the primary sheet around the orientation direction of the graphite particles (A) as an axis thereby yielding a formed body; and
slicing the formed body at an angle of 0 to 30 degrees to any normal line extending on the primary sheet surfaces.

15. The process for producing a thermally conductive sheet according to claim 14, wherein the formed body is sliced in the temperature range from the Tg of the organic polymeric compound (B)+30° C. to the Tg−40° C.

16. The process for producing a thermally conductive sheet according to claim 14, wherein the slicing of the formed body is performed by use of a slicing member having a flat and smooth board surface having a slit, and a blade protruded from the slit, and
the length of the blade protruded from the slit can be adjusted in accordance with a desired thickness of the thermally conductive sheet.

17. The process for producing a thermally conductive sheet according to claim 16, wherein the slicing is performed while the flat and smooth board surface and/or the blade is cooled into a temperature within the range of −80° C. to 5° C.

18. The process for producing a thermally conductive sheet according to claim 14, wherein the formed body is sliced into a thickness not more than 2 times the weight-average particle diameter obtained by classifying the graphite particles (A).

19. A radiator, comprising a thermally conductive sheet according to claim 1, interposed between a heat generating body and a heat radiating body.

20. A heat spreader, comprising a thermally conductive sheet according to claim 1 attached to a formed body which is made of a raw material having a thermal conductivity of 20 W/mK or more and is in the form of a plate or form similar to a plate.

21. A heat sink, comprising a thermally conductive sheet according to claim 1 attached to a formed body which is made of a raw material having a thermal conductivity of 20 W/mK or more and is in the form of a bulk or a bulk having a fin.

22. A heat radiating housing, comprising a thermally conductive sheet according to claim 1 attached to an inner surface of a box which is made of a raw material having a thermal conductivity of 20 W/mK or more.

23. A heat radiating electronic substrate or electric substrate, comprising a thermally conductive sheet according to claim 1 attached to an insulated region of an electronic substrate or electric substrate.

24. A heat radiating pipe or heating pipe, comprising a thermally conductive sheet according to claim 1 used in a joint region of heat radiating pipe pieces or heating pipe pieces, and/or a joint region which is to be fitted to an object to be cooled or object to be heated.

25. A heat radiating luminous body, comprising a thermally conductive sheet according to claim 1 attached to a back surface area of an electric lamp, a fluorescent light, or an LED.

26. A semiconductor device, comprising a semiconductor and a thermally conductive sheet according to claim 1, wherein the thermally conductive sheet diffuses heat generated from the semiconductor.

27. An electronic instrument, comprising an electronic component and a thermally conductive sheet according to claim 1, wherein the thermally conductive sheet diffuses heat generated from the electronic component.

28. A light emitting device, comprising a light emitting element and a thermally conductive sheet according to claim 1, wherein the thermally conductive sheet diffuses heat generated from the light emitting element.

29. The process for producing a thermally conductive sheet according to claim 13, wherein the formed body is sliced in the temperature range from the Tg of the organic polymeric compound (B)+30° C. to the Tg−40° C.

30. The process for producing a thermally conductive sheet according to claim 13, wherein the slicing of the formed body is performed by use of a slicing member having a flat and smooth board surface having a slit, and a blade protruded from the slit, and
the length of the blade protruded from the slit can be adjusted in accordance with a desired thickness of the thermally conductive sheet.

31. The process for producing a thermally conductive sheet according to claim 30, wherein the slicing is performed while the flat and smooth board surface and/or the blade is cooled into a temperature within the range of −80° C. to 5° C.

32. The process for producing a thermally conductive sheet according to claim 13, wherein the formed body is sliced into a thickness not more than 2 times the weight-average particle diameter obtained by classifying the graphite particles (A).

33. A radiator, comprising a thermally conductive sheet produced by the process according to claim 13 interposed between a heat generating body and a heat radiating body.

34. A heat spreader, comprising a thermally conductive sheet produced by the process according to claim 13 attached to a formed body which is made of a raw material having a thermal conductivity of 20 W/mK or more and is in the form of a plate or form similar to a plate.

35. A heat sink, comprising a thermally conductive sheet produced by the process according to claim 13 attached to a formed body which is made of a raw material having a thermal conductivity of 20 W/mK or more and is in the form of a bulk or a bulk having a fin.

36. A heat radiating housing, comprising a thermally conductive sheet produced by the process according to claim 13 attached to an inner surface of a box which is made of a raw material having a thermal conductivity of 20 W/mK or more.

37. A heat radiating electronic substrate or electric substrate, comprising a thermally conductive sheet produced by the process according to claim 13 attached to an insulated region of an electronic substrate or electric substrate.

38. A heat radiating pipe or heating pipe, comprising a thermally conductive sheet produced by the process according to claim 13 used in a joint region of heat radiating pipe pieces or heating pipe pieces, and/or a joint region which is to be fitted to an object to be cooled or object to be heated.

39. A heat radiating luminous body, comprising a thermally conductive sheet produced by the process according to claim 13 attached to a back surface area of an electric lamp, a fluorescent light, or an LED.

40. A semiconductor device, comprising a semiconductor and a thermally conductive sheet produced by the process according to claim 13, wherein the thermally conductive sheet diffuses heat generated from the semiconductor.

41. An electronic instrument, comprising an electronic component and a thermally conductive sheet produced by the process according to claim 13, wherein the thermally conductive sheet diffuses heat generated from the electronic component.

42. A light emitting device, comprising a light emitting element and a thermally conductive sheet produced by the process according to claim 13, wherein the thermally conductive sheet diffuses heat generated from the light emitting element.

43. The process for producing a thermally conductive sheet according to claim 14, wherein the formed body is sliced in the temperature range from the Tg of the organic polymeric compound (B)+30° C. to the Tg−40° C.

44. The process for producing a thermally conductive sheet according to claim 14, wherein the slicing of the formed body is performed by use of a slicing member having a flat and smooth board surface having a slit, and a blade protruded from the slit, and
the length of the blade protruded from the slit can be adjusted in accordance with a desired thickness of the thermally conductive sheet.

45. The process for producing a thermally conductive sheet according to claim 44, wherein the slicing is performed while the flat and smooth board surface and/or the blade is cooled into a temperature within the range of −80° C. to 5° C.

46. The process for producing a thermally conductive sheet according to claim 14, wherein the formed body is sliced into a thickness not more than 2 times the weight-average particle diameter obtained by classifying the graphite particles (A).

47. A radiator, comprising a thermally conductive sheet produced by the process according to claim 14 interposed between a heat generating body and a heat radiating body.

48. A heat spreader, comprising a thermally conductive sheet produced by the process according to claim 14 attached to a formed body which is made of a raw material having a thermal conductivity of 20 W/mK or more and is in the form of a plate or form similar to a plate.

49. A heat sink, comprising a thermally conductive sheet produced by the process according to claim 14 attached to a formed body which is made of a raw material having a thermal conductivity of 20 W/mK or more and is in the form of a bulk or a bulk having a fin.

50. A heat radiating housing, comprising a thermally conductive sheet produced by the process according to claim 14 attached to an inner surface of a box which is made of a raw material having a thermal conductivity of 20 W/mK or more.

51. A heat radiating electronic substrate or electric substrate, comprising a thermally conductive sheet produced by the process according to claim 14 attached to an insulated region of an electronic substrate or electric substrate.

52. A heat radiating pipe or heating pipe, comprising a thermally conductive sheet produced by the process according to claim 14 used in a joint region of heat radiating pipe pieces or heating pipe pieces, and/or a joint region which is to be fitted to an object to be cooled or object to be heated.

53. A heat radiating luminous body, comprising a thermally conductive sheet produced by the process according to claim 14 attached to a back surface area of an electric lamp, a fluorescent light, or an LED.

54. A semiconductor device, comprising a semiconductor and a thermally conductive sheet produced by the process according to claim 14, wherein the thermally conductive sheet diffuses heat generated from the semiconductor.

55. An electronic instrument, comprising an electronic component and a thermally conductive sheet produced by the process according to claim 14, wherein the thermally conductive sheet diffuses heat generated from the electronic component.

56. A light emitting device, comprising a light emitting element and a thermally conductive sheet produced by the process according to claim 14, wherein the thermally conductive sheet diffuses heat generated from the light emitting element.
